(19) United States
(12) Patent Application Publication
(10) Pub. No.: US 2026/0282413 A1
(43) Pub. Date: Sep. 17, 2026

(54) MULTI-GATE DEVICE AND MANUFACTURING METHOD THEREOF

(71) Applicant: Taiwan Semiconductor Manufacturing Company, Ltd., Hsin-Chu (TW)

(72) Inventors: Tsung-Lin Lee, Hsinchu City (TW); Chih Chieh Yeh, Taipei City (TW); Choh Fei Yeap, Hsinchu City (TW)

(21) Appl. No.: 19/281,263

(22) Filed: Jul. 25, 2025

Related U.S. Application Data
(60) Provisional application No. 63/772,095, filed on Mar. 14, 2025.

(51) Int. Cl. H10D 30/01; H10D 30/00

(52) U.S. Cl. CPC H10D 30/0191; H10D 30/0195; H10D 30/508

(57) ABSTRACT

The present disclosure provides a semiconductor device and a method of forming the same. An exemplary method includes forming a stack over a substrate, the stack comprising channel layers interleaved by sacrificial layers, a topmost one of the sacrificial layers above a topmost one of the channel layers, patterning the stack to form a fin-shaped structure, forming a dummy gate stack over the fin-shaped structure, depositing a gate sidewall spacer on a sidewall of the dummy gate stack, removing the dummy gate stack to form a gate trench, releasing the channel layers as channel members by removing the sacrificial layers, forming a metal gate structure in the gate trench. The metal gate structure wraps around the channel members. The metal gate structure includes a first portion above a topmost one of the channel members and interfacing a bottom surface of the gate sidewall spacer.

### PRIORITY DATA

This application claims priority to U.S. Provisional Patent Application No. 63/772,095 filed on Mar. 14, 2025, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend around a channel region to provide access to the channel region on all four sides.

To improve the performance of GAA transistors, efforts are being invested in developing structures in the channel regions that improve the uniformity of metal gate critical dimensions (CD) and channel member thicknesses. While conventional channel region structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a flowchart of an exemplary method for making a semiconductor device, in accordance with some embodiments of the present disclosure.

FIGS. 2A, 3A, 4A, 5A, and 6A illustrate perspective views of a semiconductor device constructed according to the method in FIG. 1, in accordance with some embodiments.

FIGS. 2B, 3B, 4B, 5B, and 6B illustrate cross-sectional views in a Y-Z plane of a portion of the semiconductor device in respective perspective views during fabrication processes according to the method of FIG. 1, in accordance with some embodiments of the present disclosure.

FIGS. 7A, 8A, 9A, 10A, 11A, 12A, 13A, 14A, 15A, 16A, 17A, 18A, 19A, 20A, 21A, and 22A illustrate cross-sectional views in a Y-Z plane of a portion of the semiconductor device in respective perspective views during fabrication processes according to the method of FIG. 1, in accordance with some embodiments of the present disclosure.

FIGS. 7B, 8B, 9B, 10B, 11B, 12B, 13B, 14B, 15B, 16B, 17B, 18B, 19B, 20B, 21B, and 22B illustrate cross-sectional views in a X-Z plane of a portion of the semiconductor device in respective perspective views during fabrication processes according to the method of FIG. 1, in accordance with some embodiments of the present disclosure.

FIGS. 23, 24, 25, 26, and 27 illustrate alternative embodiments of the cross-sectional view in an X-Z plane of a portion of the semiconductor device, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure provides a gate-all-around (GAA) transistor with improved uniformity of both metal gate critical dimensions (CD) and channel member thicknesses in its channel region.

The channel region of a GAA transistor may be formed using vertically stacked semiconductor nanostructures, referred to herein as “channel members.” These channel members may take various shapes, such as nanowires, nanosheets, bars, columns, posts, or other suitable configurations. Depending on their specific geometry, GAA transistors may also be referred to as nanowire transistors or nanosheet transistors. Regardless of shape, each channel member extends between and is coupled to a pair of epitaxial features located in opposing source/drain (S/D) regions. These epitaxial features may also be referred to as source/drain features or source/drain epitaxial features. Source/drain region(s) may refer to a source or a drain, individually or collectively dependent upon the context. In a typical replacement gate process, a dummy gate stack is initially removed to form a gate trench that exposes the stacked channel layers. These channel layers are then released by selectively removing the interleaving sacrificial layers, resulting in channel members. A metal gate structure is subsequently formed in the gate trench such that it wraps around the channel members. Inner spacers are positioned between the metal gate structure and the source/drain features to prevent direct contact (interfacing) between them. The portion of the metal gate structure situated between adjacent channel members is commonly referred to as the inner metal gate, while the portion disposed above the topmost channel member is referred to as the outer metal gate. The CD of the inner metal gate is defined by the spacing between opposing inner spacers, whereas the CD of the outer metal gate is defined by the spacing between opposing gate sidewall spacers. Variations in these spacings may lead to CD inconsistencies between the inner and outer metal gates. Additionally, during the removal of the dummy gate stack, the topmost channel layer may experience etching loss from above due to limited etch selectivity. As a result, the topmost channel member may become thinner than the underlying channel members, introducing inconsistency in channel member thickness.

The present disclosure provides embodiments of a semiconductor device in which a sacrificial semiconductor layer is disposed above the topmost channel layer. This additional sacrificial layer, located in the channel region, serves two primary purposes. First, it provides etching protection to the topmost channel layer during the removal of the dummy gate stack, thereby mitigating etch-induced thinning of the topmost channel member. Thus, the uniformity of the channel member thicknesses is improved. Second, it reserves a defined space above the topmost channel layer to accommodate the bottom portion of the outer metal gate. This portion of the metal gate in this defined space is separately referred to as top metal gate in the context. This reserved space is laterally defined by the opposing inner spacers, in the same manner as the spacing for the inner metal gate. As a result, the top metal gate exhibits a CD that matches that of the inner metal gate. Even though the outer metal gate may still have a different CD, since the inner metal gate and the top metal gate are the portions of the metal gate that directly engage the channel members, the uniformity of the metal gate CDs is improved.

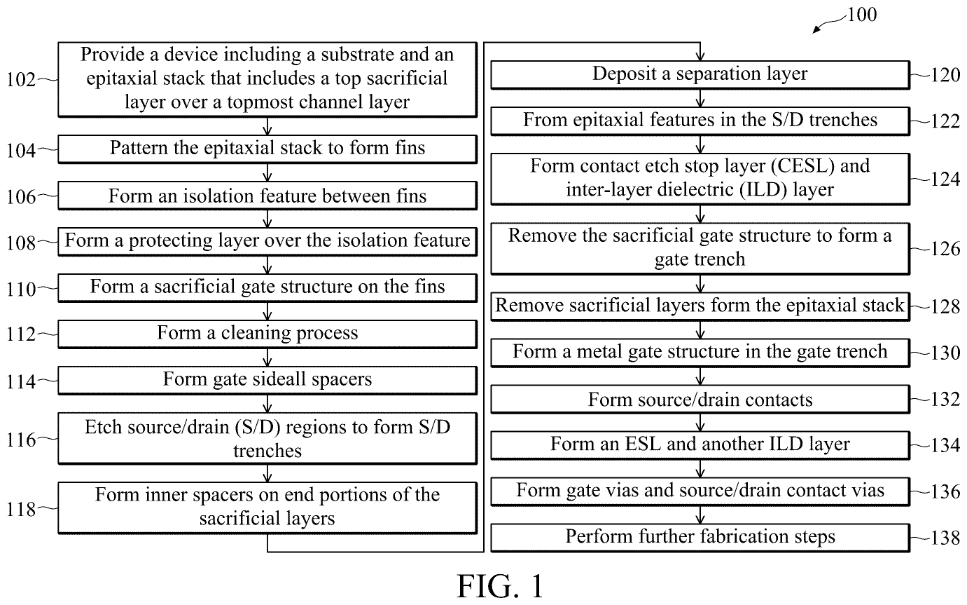

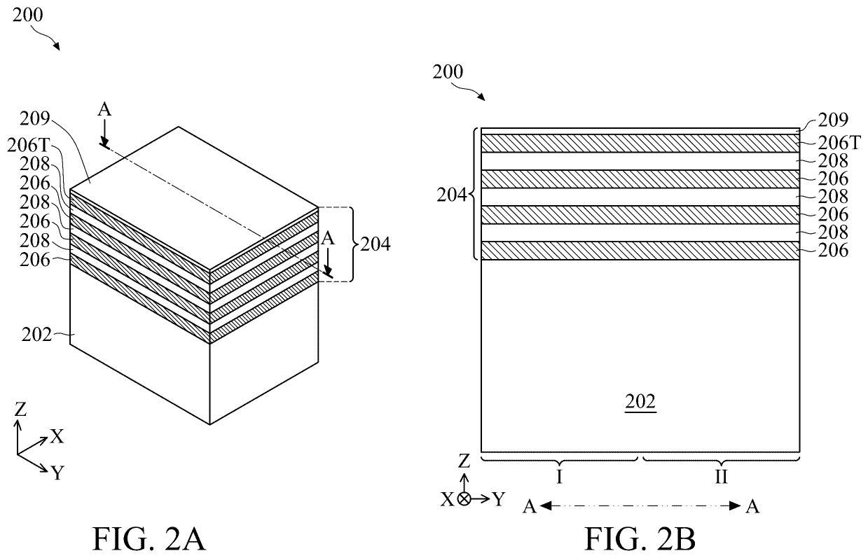

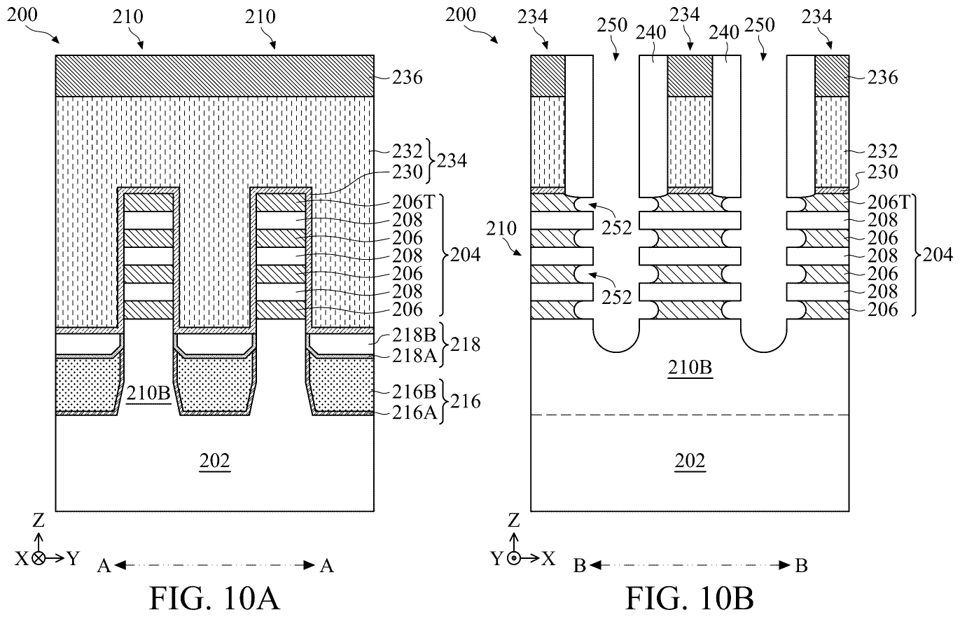

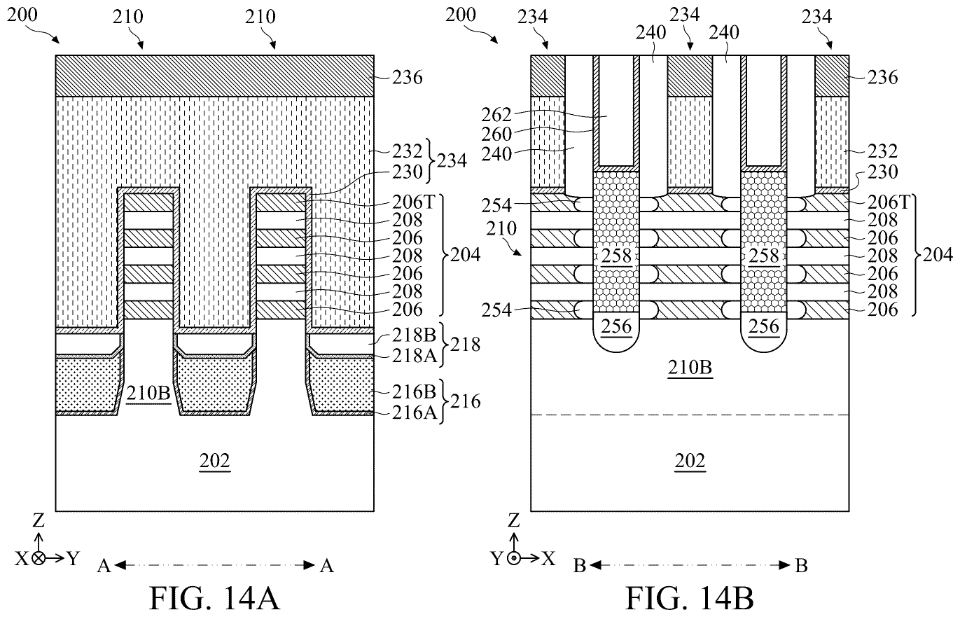

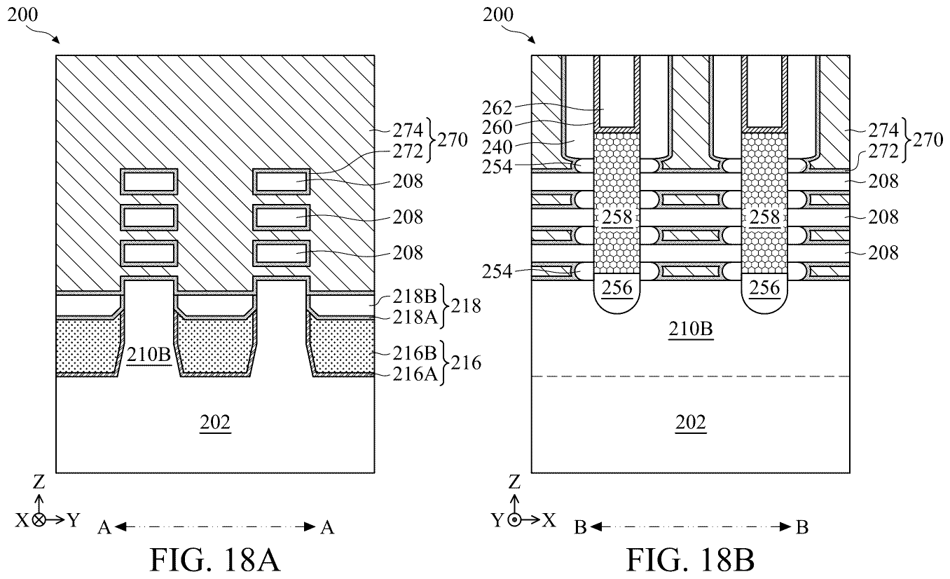

FIG. 1 illustrates a flow chart of a method 100 for fabricating a semiconductor device according to various embodiments of the present disclosure. Additional processing is contemplated by the present disclosure. Additional operations can be provided before, during, and after method 100, and some of the operations described can be moved, replaced, or eliminated for additional embodiments of method 100. FIG. 1 is described below in conjunction with FIGS. 2A through 27.

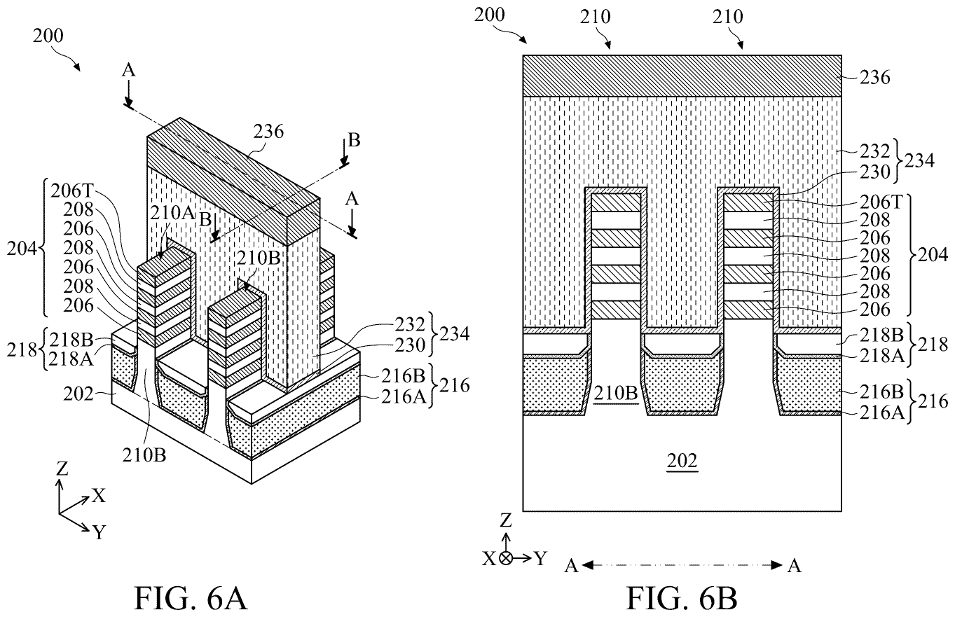

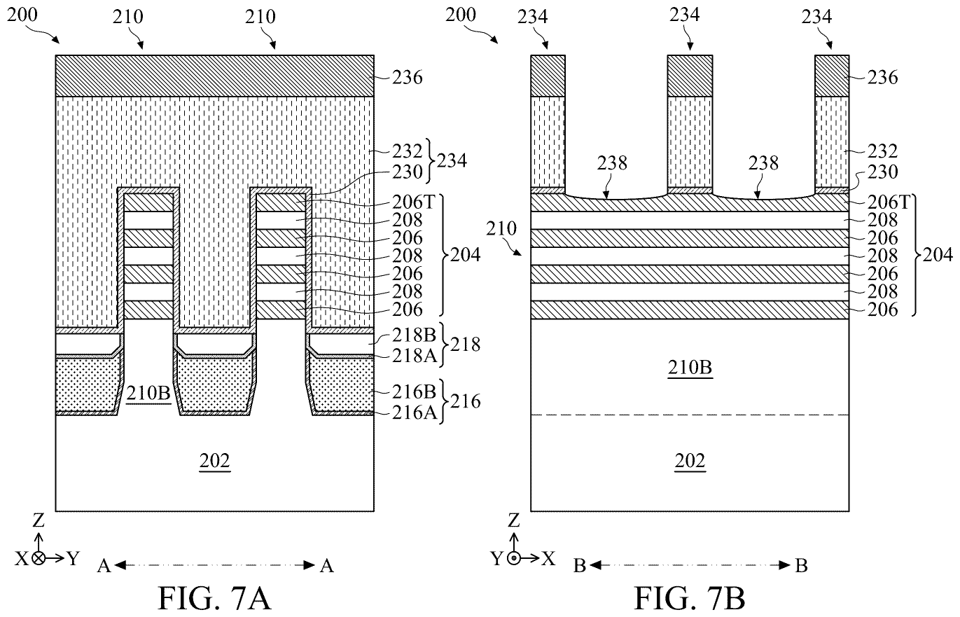

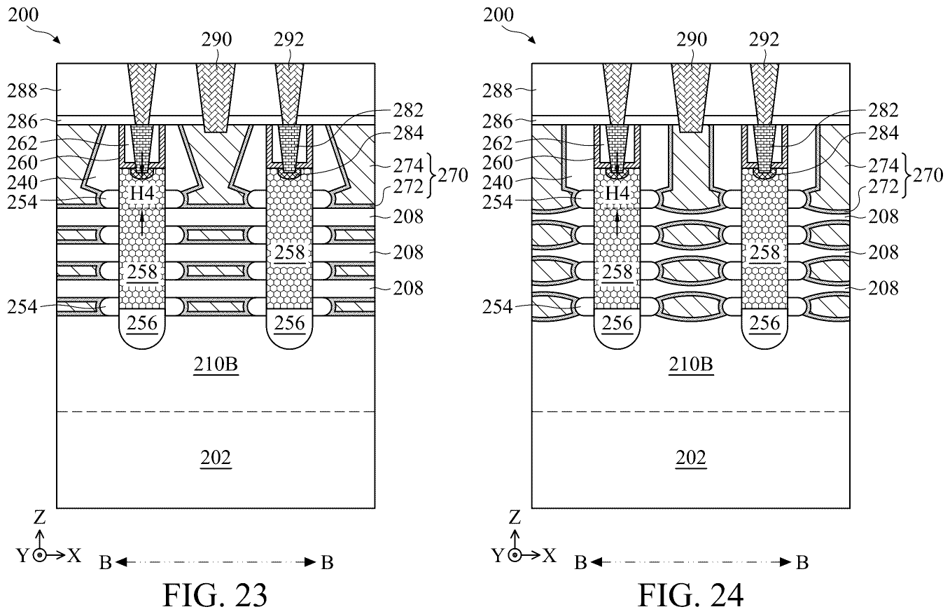

FIGS. 2A, 3A, 4A, 5A, and 6A represent perspective views of an embodiment of a semiconductor device (or device) 200 according to various stages of the method 100 of FIG. 1. FIGS. 2B, 3B, 4B, 5B, and 6B are cross-sectional views taken in the Y-Z plane along the A-A line in the corresponding figures numbered with suffix “A”, which cut through a gate region and perpendicular to a lengthwise direction of channel regions of the device 200. FIGS. 7A to 22A with suffix “A” are cross-sectional views of the device 200 as in FIG. 6A taken in the Y-Z plane along the A-A line in subsequent stages of the method 100 of FIG. 1. FIGS. 7B to 22B with suffix “B” are cross-sectional views of the device 200 as in FIG. 6A taken in the X-Z plane along the B-B line in subsequent stages of the method 100 of FIG. 1. FIGS. 23 to 27 are alternative embodiments of the cross-sectional view of the device 200 as in FIG. 6A taken in the X-Z plane along the B-B line at the conclusion of operation 136 of the method 100 of FIG. 1. FIGS. 2A through 27 have been simplified for the sake of clarity to better understand the inventive concepts of the present disclosure. Additional features can be added in the device 200, and some of the features described below can be replaced, modified, or eliminated in other embodiments of the device 200.

In some embodiments, the device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof.

Referring to FIGS. 1 and 2A-2B, the method 100 at operation 102 provides a device 200 having a substrate 202 and a stack 204 disposed on the substrate 202. In some embodiments, the substrate 202 is a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the n-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). In the depicted embodiment, the stack 204 further includes a top sacrificial layer 206T disposed on the topmost one of the channel layers 208. In some instances, compositions of the sacrificial layers 206 and the top sacrificial layer 206T are substantially the same, such as silicon germanium (SiGe). The top sacrificial layer 206T functions to protect the topmost one of the channel layers 208 from etching loss during fabrication processes and further improves metal gate CD uniformity, which will be explained in further detail below.

It is noted that three (3) layers of the sacrificial layers 206 and three (3) layers of the channel layers 208, together with one (1) layer of the top sacrificial layer 206T, are alternately arranged as illustrated in FIG. 2, which is for illustrative purposes only and not intended to be limiting beyond what is specifically recited in the claims. It can be appreciated that any number of sacrificial layers 206 and channel layers 208, together with one layer of the top sacrificial layer 206T, may be formed in the stack 204. The number of layers depends on the desired number of channels members for the device 200. In some embodiments, the number of channel layers 208 is between 1 and 20.

In some embodiments, all sacrificial layers 206 may have a substantially uniform first thickness ranging from approximately 5 nm to 20 nm, while all channel layers 208 may have a substantially uniform second thickness ranging from approximately 3 nm to 10 nm. The first and second thicknesses may be the same or different. The channel layers 208 function as channel members for a subsequently formed multi-gate device, with the second thickness selected based on device performance requirements. The sacrificial layers 206 located in the channel regions are ultimately removed and serve to define the vertical spacing between adjacent channel members, and the first thickness is likewise determined based on performance considerations. Additionally, the top sacrificial layer 206T may have a third thickness equal to or greater than the first thickness of the sacrificial layers 206. As explained in further detail below, the top sacrificial layer 206T is also removed during processing and defines the thickness of a lower portion of an outer metal gate disposed on the topmost channel member. The third thickness is selected to ensure sufficient space is reserved to facilitate the metal gate fill process. Accordingly, in some embodiments, the third thickness of the top sacrificial layer 206T exceeds the first thickness of the sacrificial layers 206. In some embodiments, the ratio of the third thickness of the top sacrificial layer 206T to the first thickness of the sacrificial layers 206 ranges from about 1.2:1 to about 2:1. Further, in some embodiment, the top sacrificial layer 206T may differ in element concentration from underneath sacrificial layers 206. For example, for the top sacrificial layer 206T and the underneath sacrificial layers 206 both having silicon germanium (SiGe), the top sacrificial layer 206T may have a germanium concentration in molar ratio that is higher than that of the underneath sacrificial layers 206. The different germanium concentration allows the top sacrificial layer 206T to be more easily removed from certain corner areas in subsequent processes.

In the depicted embodiment, the stack 204 further includes a capping layer 209 disposed on the top sacrificial layer 206T. In some embodiments, compositions of the capping layer 209 and the channel layers 208 are substantially the same, such as silicon (Si). The capping layer 209 functions to protect the stack 204 from damages during subsequent fin formation and STI formation processes. The capping layer 209 may be thinner than either of the channel layers 208 and the sacrificial layers 206. In some embodiments, a thickness of the capping layer 209 may be between about 1 nm and about 2 nm.

The semiconductor layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204, and the layers 206 and 208 are also referred to as the epitaxial layers 206 and 208. As stated above, in at least some examples, the sacrificial layers 206 include an epitaxially grown silicon germanium (SiGe) layer, the channel layers 208 include an epitaxially grown silicon (Si) layer, and the top sacrificial layer 206T includes an epitaxially grown silicon germanium (SiGe) layer. In some embodiments, the sacrificial layers 206, the channel layers 208, and the top sacrificial layer 206T are substantially dopant-free, where for example, no intentional doping is performed during the epitaxial growth processes for the epitaxial stack 204. In some embodiments, the top surface of the substrate 202 is in a (100) crystalline plane, and accordingly each layer of the epitaxial stack 204 has a (100) top surface. In some alternative embodiments, the top surface of the substrate is in a (110) crystalline plane, and accordingly each layer of the epitaxial stack 204 has a (110) top surface.

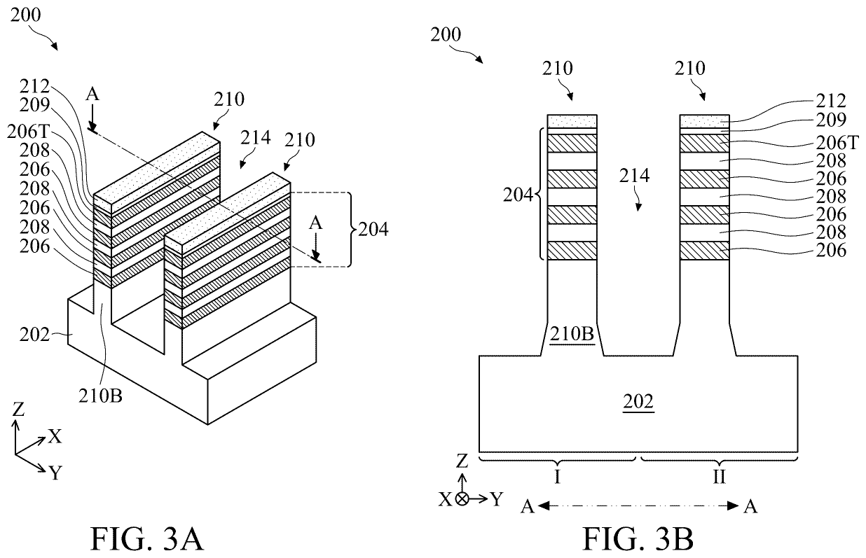

Referring to FIGS. 1 and 3A-3B, the method 100 at operation 104 patterns the epitaxial stack 204 to form semiconductor fins 210 (also referred to as fins 210). The fins 210 may be patterned from the epitaxial stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods.

In the illustrated embodiment, a hard mask layer 212 is formed over the epitaxial stack 204 prior to patterning the fins 210. In some embodiments, the hard mask layer 212 includes an oxide layer (e.g., a pad oxide layer that may include silicon oxide) and a nitride layer (e.g., a pad nitride layer that may include silicon nitride) formed over the oxide layer. The oxide layer may act as an adhesion layer between the epitaxial stack 204 and the nitride layer. In some embodiments, the oxide layer includes thermally grown oxide, chemical vapor deposition (CVD)-deposited oxide, and/or atomic layer deposition (ALD)-deposited oxide. In some embodiments, the nitride layer is deposited by CVD and/or other suitable technique.

The hard mask layer 212 is patterned into a mask pattern. Through openings defined in the patterned hard mask layer 212, the etching process forms trenches extending sequentially through the epitaxial stack 204 and a top portion of the substrate 202. The trenches define the fins 210. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fins 210 by etching the epitaxial stack 204 and a top portion of the substrate 202. The patterned top portion of the substrate 202 is also denoted as a fin-shaped base 210B. The fin-shaped base 210B may still be considered as a top part of the substrate 202 as the context requires. In the depicted embodiment, the fins 210, which includes the patterned epitaxial stack 204 and the fin-shaped base 210B, extends vertically along the Z direction and lengthwise along the X-direction. In some embodiments, the fins 210 measures between about 6 nm and about 80 nm wide along the Y-direction, and a distance between opposing sidewalls of two adjacent fins 210 measures between about 6 nm and about 115 nm along the Y-direction. In FIGS. 3A-3B, two (2) fins 210 are spaced apart along the Y-direction. But the number of the fins 210 is not limited to two, and may be as small as one or more than two.

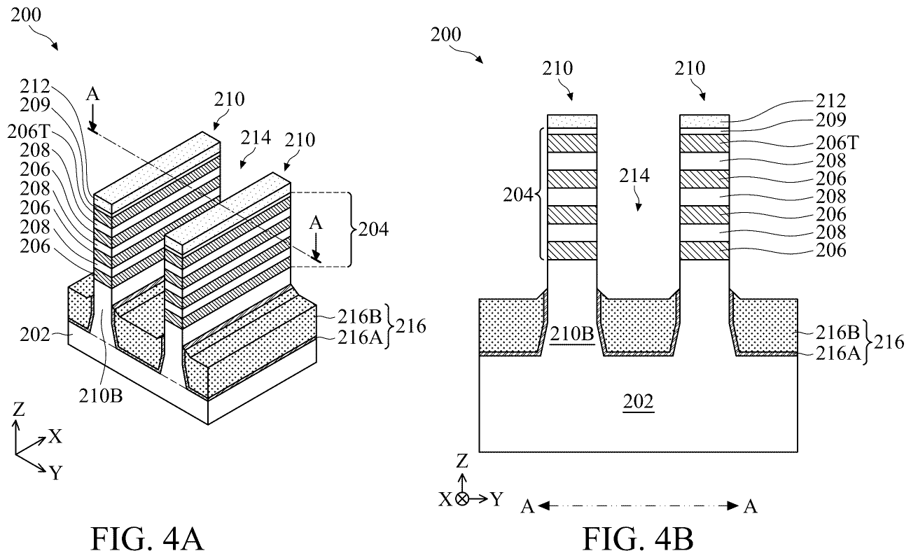

Referring to FIGS. 1 and 4A-4B, the method 100 at operation 106 forms an isolation feature, such as a shallow trench isolation (STI) feature on sidewalls of the fin-shaped bases 210B. By way of example, in some embodiments, the STI feature 216 includes a liner 216A and a fill layer 216B. The liner 216A and the fill layer 216B include different material compositions. In some embodiments, the liner 216A is a nitride layer (e.g., silicon nitride) or an amorphous silicon layer. In some embodiments, the fill layer 216B may include silicon oxide, silicon nitride, silicon oxynitride, fluorine-doped silicate glass (FSG), a low-k dielectric, combinations thereof, and/or other suitable materials. The dielectric materials of the STI feature 216 are first deposited over the substrate 202, filling the trenches 214. In various examples, the dielectric materials may be deposited by a CVD process, a SACVD process, a flowable CVD process, an ALD process, a PVD process, and/or other suitable process. In some embodiments, after deposition of the dielectric layer, the device 200 may be annealed, for example, to improve the quality of the dielectric materials.

In some embodiments of forming the STI feature, after deposition of the dielectric materials, the deposited dielectric materials are thinned and planarized, for example by a chemical mechanical polishing (CMP) process. In some embodiments, the hard mask layer 212 functions as a CMP stop layer. Subsequently, the dielectric materials interposing the fins 210 are recessed. Still referring to the example of FIGS. 4A and 4B, the STI feature 216 is recessed providing the fins 210 extending through the STI feature 216. In some embodiments, the recessing process may include a dry etching process, a wet etching process, and/or a combination thereof. In some embodiments, a recessing depth is controlled (e.g., by controlling an etching time) so as to expose upper portion of the fin-shaped bases 210B. The top surface of the STI feature 216 extends laterally between opposing sidewalls of two adjacent fin-shaped bases 210B. In the illustrated embodiment, the top surface of the STI feature 216 has a dishing profile due to loading effect during etching process. The edges of the dishing profile of the STI feature 216 intersect sidewalls of the fin-shaped bases 210B. In the illustrated embodiment, each layer of the epitaxial stack 204 is exposed, and the top surface of the STI feature 216 is recessed below the bottommost epitaxial layer 206. In some embodiments, a dielectric constant of the STI feature 216 ranges between about 3 and about 5.

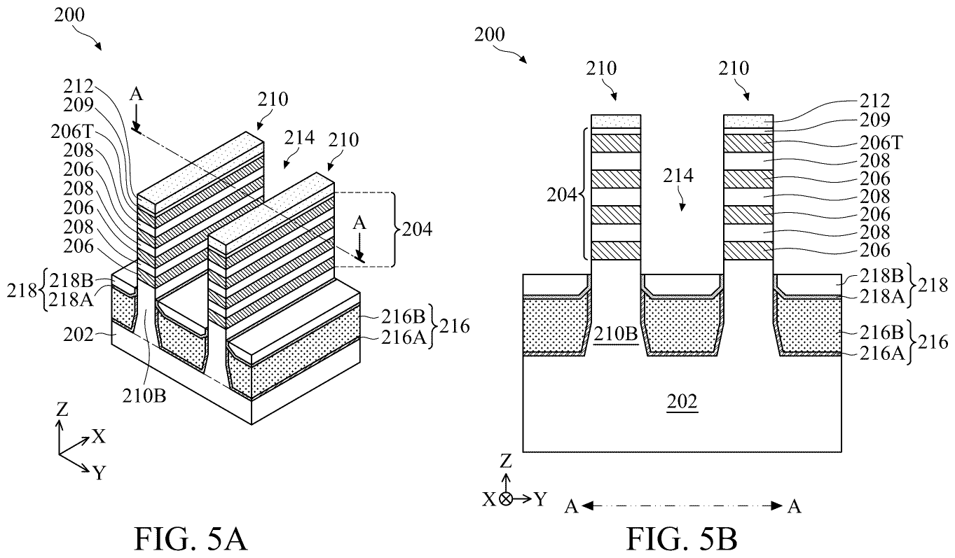

Referring to FIGS. 1 and 5A-5B, the method 100 at operation 108 forms an STI protecting layer 218 over the STI feature 216. A composition of the STI protecting layer 218 is different from the STI feature 216, particularly different from the fill layer 216B. In some embodiments, the STI feature 216 is an oxide-based material with a dielectric constant from about 3 to about 5. In some embodiments, the STI feature 216 mainly includes silicon oxide, and the STI protecting layer 218 includes silicon nitride, silicon carbonitride (SiCN), or silicon oxynitride (SiON). By way of example, in some embodiments, the STI protecting layer 218 includes a liner 218A and a fill layer 218B. The liner 218A and the fill layer 218B may both include nitride (e.g., silicon nitride) but differ in nitrogen concentration. In furtherance of some embodiments, the liner 218A is richer in nitrogen than the fill layer 218B. In various embodiments, nitride-containing materials are first deposited over the STI feature 216, filling the trenches with nitride. In various examples, the nitride-containing materials may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the STI protecting layer 218. The fin-shaped bases 210B rise above the STI protecting layer 218 after the recessing. In the illustrated embodiment, the top surface of the STI protecting layer 218 is substantially flat. In an alternative embodiment, the top surface of the STI protecting layer 218 may have a dishing profile due to loading effect during etching process, similar to the top surface of the STI feature 216. The edges of the dishing profile of the STI protecting layer 218 intersect sidewalls of the fin-shaped bases 210B. In the illustrated embodiment, each layer of the epitaxial stack 204 is exposed, and the top surface of the STI protecting layer 218 is recessed below the bottommost epitaxial layer 206. In some embodiments, a dielectric constant of the STI protecting layer 218 ranges between about 7 and about 9. In furtherance of some embodiments, the dielectric constant of the STI protecting layer 218 is greater than that of the STI feature 216. During the recessing process, the hard mask layer 212 and the capping layer 209 may be consumed. Alternatively, after the recessing process, the hard mask layer 212 and the capping layer 209 may be removed, for example, by a wet etching process using H₃PO₄ or other suitable etchants.

Referring to FIGS. 1 and 6A-6B, the method 100 at operation 110 forms a sacrificial (dummy) gate structure 234. In FIG. 6A, one sacrificial gate structure 234 is shown, but the number of the sacrificial gate structures 234 is not limited to one, two, or more sacrificial gate structures, which are arranged in the X-direction (as in FIG. 7B). The sacrificial gate structure 234 is formed over portions of the fins 210 which are to be channel regions. The sacrificial gate structure 234 defines channel regions of the to-be-formed transistors. The sacrificial gate structure 234 includes a sacrificial gate dielectric layer 230 and a sacrificial gate electrode layer 232. The sacrificial gate structure 234 is formed by first blanket depositing the sacrificial gate dielectric layer 230 over the fins 210. A sacrificial gate electrode layer 232 is then deposited on the sacrificial gate dielectric layer 230 and over the fins 210. The sacrificial gate electrode layer 232 includes silicon such as polycrystalline silicon or amorphous silicon. In some embodiments, the sacrificial gate electrode layer 232 is subjected to a planarization operation. The sacrificial gate dielectric layer 230 and the sacrificial gate electrode layer 232 may be deposited using CVD, including LPCVD and PECVD, PVD, ALD, or other suitable process. Subsequently, a mask layer 236 is formed over the sacrificial gate electrode layer 232. The mask layer 236 may include a pad silicon oxide layer and a silicon nitride mask layer. Subsequently, a patterning operation is performed on the mask layer 236, and sacrificial gate dielectric and electrode layers are patterned into the sacrificial gate structure 234. By patterning the sacrificial gate structure 234, the fins 210 are partially exposed on opposite sides of the sacrificial gate structure 234, thereby defining source/drain (S/D) regions.

Referring to FIGS. 1 and 7A-7B, the method 100 at operation 112 may optionally perform a cleaning process to clean surfaces of the device 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. As shown in FIG. 7B, the patterning of the sacrificial gate structures 234 during operation 110 and/or the cleaning process during operation 112 may result in partial etching of the top sacrificial layer 206T due to limited etch selectivity of the etchant(s). Consequently, the top surface of the top sacrificial layer 206T may exhibit a dishing profile 238, wherein the central point of the dishing profile 238 is positioned lower than the bottom surface of the sacrificial gate dielectric layer 230. Despite this etching loss, the top sacrificial layer 206T effectively protects the topmost channel layer 208 from etching loss, thereby preserving the thickness integrity of the topmost channel layer 208.

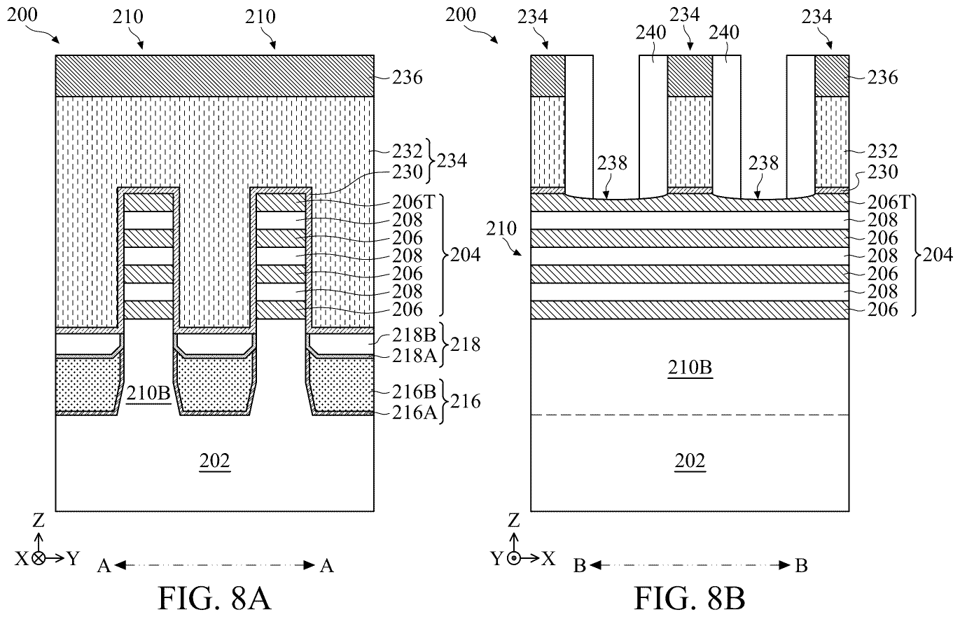

Referring to FIGS. 1 and 8A-8B, the method 100 at operation 114 forms gate sidewall spacers 240 on sidewalls of the sacrificial gate structure 234. The gate sidewall spacers 240 may include a dielectric material such as silicon oxide, silicon nitride, silicon carbide, silicon oxynitride, SiCN, silicon oxycarbide, SiOCN, and/or combinations thereof. In some embodiments, the gate sidewall spacers 240 include multiple layers, such as main spacer walls, liner layers, and the like. By way of example, the gate sidewall spacers 240 may be formed by blanket depositing a dielectric material layer in a conformal manner over the sacrificial gate structure 234 using processes such as, a CVD process, a subatmospheric CVD (SACVD) process, a flowable CVD process, an ALD process, a PVD process, or other suitable process. Subsequently, an anisotropic etching process is performed to remove horizontal portions of the dielectric material layer, while vertical portions of the dielectric material layer remain on the sidewalls of the sacrificial gate structure 234 as the gate sidewall spacers 240. The gate sidewall spacers 240 may be a single layer or a multilayer. In one embodiment, the gate sidewall spacers 240 include a first layer and a second layer disposed over the first layer. The first layer may include silicon oxynitride and the second layer may include silicon nitride. In some instances, the gate sidewall spacers 240 measure between about 3 nm and about 8 nm thick along the X-direction. Due to the dishing profile 238 of the top sacrificial layer 206T, extending between the inner sidewall (facing the sacrificial gate structure 234) of the gate sidewall spacer 240 and the outer sidewall (opposing the inner sidewall and facing the S/D region) of the gate sidewall spacer 240, the bottom surface of the gate sidewall spacer 240 may have a curvature profile. Due to the curvature profile, the bottom surface of the gate sidewall spacers 240 may be below the bottom surface of the sacrificial gate dielectric layer 230.

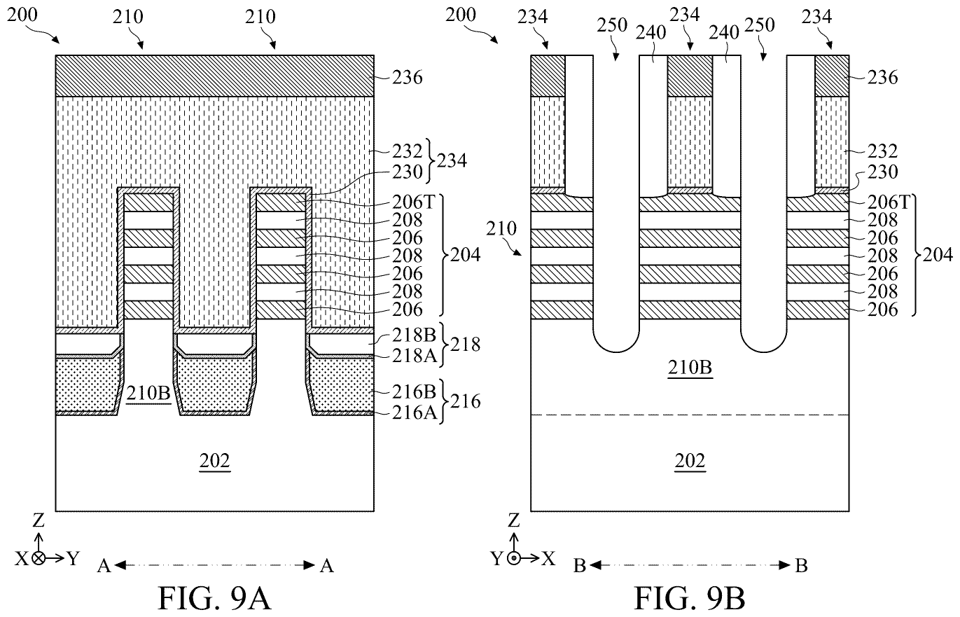

Referring to FIGS. 1 and 9A-9B, the method 100 at operation 116 recesses portions of the fins 210 to form S/D trenches (or S/D recesses) 250 in the S/D regions. The top sacrificial layer 206T and the underneath stacked epitaxial layers 206 and 208 are etched through in the S/D regions. In many embodiments, the S/D trenches 250 is formed in a suitable etching process, such as a dry etching process, a wet etching process, or an RIE process. The etching process may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The etchant is selected such that a top portion of the fin-shaped base 210B is also recessed.

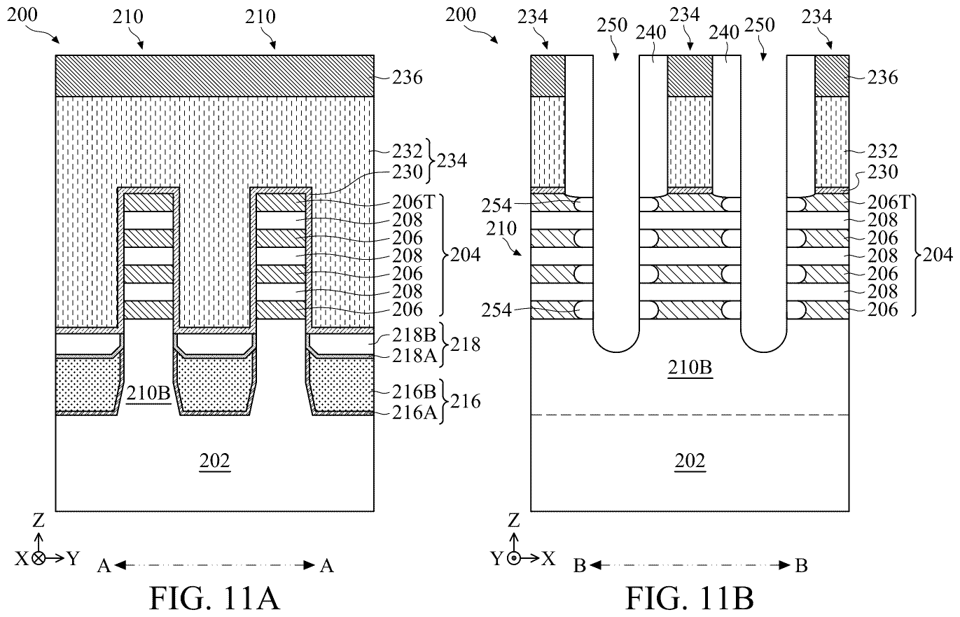

Referring to FIGS. 1, 10A-10B, and 11A-11B, the method 100 at operation 118 forms inner spacers 254 abutting end portions of the top sacrificial layer 206T and the sacrificial layers 206. Operation 118 may first laterally recess the end portions of the top sacrificial layer 206T and the underneath epitaxial layers 206, thereby forming cavities 252 to be filled by a dielectric material as the inner spacers 254, as shown in FIGS. 11A-11B. The top sacrificial layer 206T and the underneath sacrificial layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, operation 118 may first selectively oxidize lateral ends of the top sacrificial layer 206T and the underneath sacrificial layers 206 that are exposed in the S/D trenches 250 to increase the etch selectivity with respect to the channel layers 208. In some examples, the oxidation process may be performed by exposing the device 200 to a wet oxidation process, a dry oxidation process, or a combination thereof. The cavities 252 also expose end portions of the channel layers 208 and a bottom surface of the gate sidewall spacers 240. Due to the dishing profile of the top sacrificial layer 206T, the end portions of the top sacrificial layer 206T located beneath the gate sidewall spacers 240 are thinner than the central portion located beneath the sacrificial gate structure 234. Consequently, the topmost cavity 252 formed by etching the end portions of the top sacrificial layer 206T is thinner than the other underlying cavities 252.

Next, operation 118 forms inner spacers 254 in the cavities 252, as shown in FIGS. 11A-11B. By way of example, operation 118 may include blanket depositing an inner spacer material layer in the S/D trenches 250. Particularly, the inner spacer material layer is deposited on the recessed lateral ends of the top sacrificial layer 206T and the underneath epitaxial layers 206. The inner spacer material layer may include silicon nitride (SiN), silicon carbonitride (SiCN), silicon oxycarbide (SiOC), silicon oxycarbonitride (SiOCN), or other suitable dielectric materials. In some embodiments, the inner spacer material layer includes the same material composition as in the gate sidewall spacers 240. In some embodiments, the inner spacer material layer includes a different material composition from the gate sidewall spacers 240. In some embodiments, the inner spacer material layer is deposited as a conformal layer with substantially uniform thickness on different surfaces. The inner spacer material layer can be formed by ALD or any other suitable method. By conformally forming the inner spacer material layer, a volume of the cavities is reduced or completely filled. After the inner spacer material layer is deposited, an etching operation is performed to partially remove the inner spacer material layer from the S/D trenches 250. Particularly, the inner spacer material layer is removed from the sidewalls outside of the cavities 252. By this etching, the inner spacer material layer remains substantially within the cavities 252, because of a small volume of the cavities 252. Generally, plasma dry etching etches a layer in wide and flat areas faster than a layer in concave (e.g., holes, grooves and/or slits) portions. Thus, the inner spacer material layer can remain inside the cavities 252. The remaining portions of the inner spacer material layer inside the cavities 252 provides isolation between to-be-formed metal gate structures and to-be-formed S/D epitaxial features, which are referred to as the inner spacers 254. As the topmost cavity 252 is thinner than the other underlying cavities 252, the topmost inner spacer 254 is also thinner than the other underlying inner spacers 254.

Notably, the formation of the inner spacers 254, including manufacturing steps at operation 118, may be optional. That is, the formation of the inner spacers 254 may be omitted, and the inner spacers 254 may not exist in the final structure, in some embodiments.

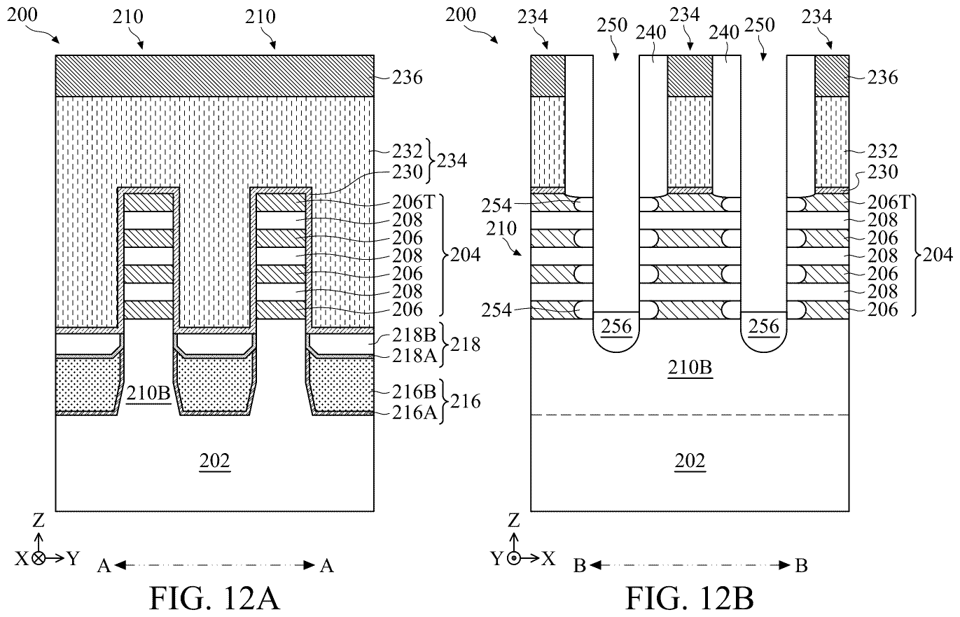

Referring to FIGS. 1 and 12A-12B, the method 100 at operation 120 deposits an interposing layer (or separation layer) 256 in the bottom of the S/D trenches 250. In some embodiments, the interposing layer 256 is a buffer epitaxial layer epitaxially grown from the top surface of the fin-shaped base 210B. By way of example, epitaxial growth of the buffer epitaxial layer 256 may be performed by VPE, ultra-high vacuum CVD (UHV-CVD), MBE, and/or other suitable epitaxial grow processes. In some embodiments, the buffer epitaxial layer 256 includes the same material as the substrate 202, such as silicon. In some alternative embodiments, the buffer epitaxial layer 256 includes a different semiconductor material other than silicon, such as SiGe, SiSn, or other suitable semiconductor material. In some embodiments, the buffer epitaxial layer 256 is dopant-free, where for example, no intentional doping is performed during the epitaxial growth process. As a comparison, in one instance, the substrate 202 is lightly doped and has a higher doping concentration than the buffer epitaxial layer 256. In some embodiments, the interposing layer 256 includes the buffer epitaxial layer and a dielectric film disposed on and covering the top surface of the buffer epitaxial layer. In the depicted embodiment, a top surface of the interposing layer 256 intersects a sidewall of the bottommost inner spacer 254. The interposing layer 256 provides a high resistance path from the S/D regions to the semiconductor substrate, such that the leakage current in the semiconductor substrate is suppressed. Notably, the formation of the interposing layer 256, including manufacturing steps at operation 120, may be optional. That is, the formation of the interposing layer 256 may be omitted, and the interposing layer 256 may not exist in the final structure, in some embodiments.

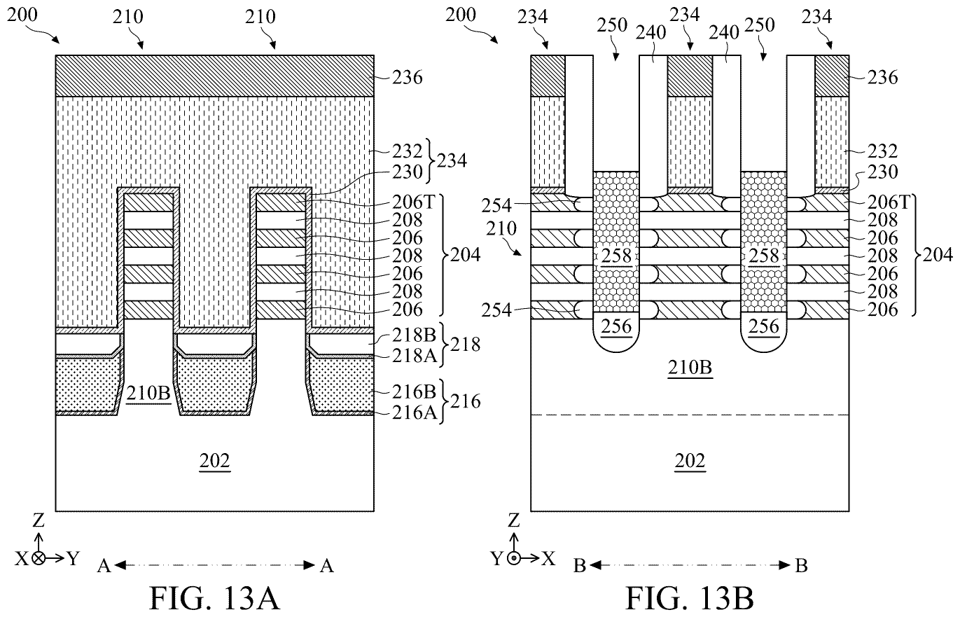

Referring to FIGS. 1 and 13A-13B, the method 100 at operation 122 forms epitaxial features 258 in the S/D trenches 250. The epitaxial features 258 are also referred to as S/D epitaxial features. The epitaxial features 258 are formed above the buffer epitaxial layer 242. The channel layers 208 connect two epitaxial features 258 in two opposing source/drain regions. In some embodiments, a dielectric film (not shown) may optionally be deposited on the top surface of the interposing layer 256 to separate the epitaxial features 258 from contacting the interposing layer 256. In other words, the bottom surface of the epitaxial features 246 may rest on the top surface of the dielectric film. The dielectric film further suppresses the leakage current from the source/drain regions. Alternatively, the bottom surface of the epitaxial features 258 may directly rest on the top surface of the interposing layer 256, as shown in the depicted embodiment. In some embodiments, the epitaxial features 258 include epitaxially grown semiconductor materials such as epitaxially grown silicon, germanium, or silicon germanium. The epitaxial features 258 can be formed by any epitaxy processes including chemical vapor deposition (CVD) techniques (for example, vapor phase epitaxy and/or Ultra-High Vacuum CVD), molecular beam epitaxy, other suitable epitaxial growth processes, or combinations thereof. The epitaxial features 258 may be doped with n-type dopants and/or p-type dopants. In some embodiments, for n-type transistors, the epitaxial features 258 include silicon and can be doped with carbon, phosphorous, arsenic, other n-type dopant, or combinations thereof (for example, forming Si:C S/D epitaxial features, Si:P S/D epitaxial features, or Si:C:P S/D epitaxial features). In some embodiments, for p-type transistors, the epitaxial features 246 include silicon germanium or germanium, and can be doped with boron, other p-type dopant, or combinations thereof (for example, forming Si:Ge:B S/D epitaxial features). The epitaxial features 258 may include multiple epitaxial semiconductor layers having different levels of dopant density. In some embodiments, annealing processes (e.g., rapid thermal annealing (RTA) and/or laser annealing) are performed to activate dopants in the epitaxial features 258. In the depicted embodiment, the top surface of the epitaxial features 258 intersects the sidewalls of the gate sidewall spacers 240.

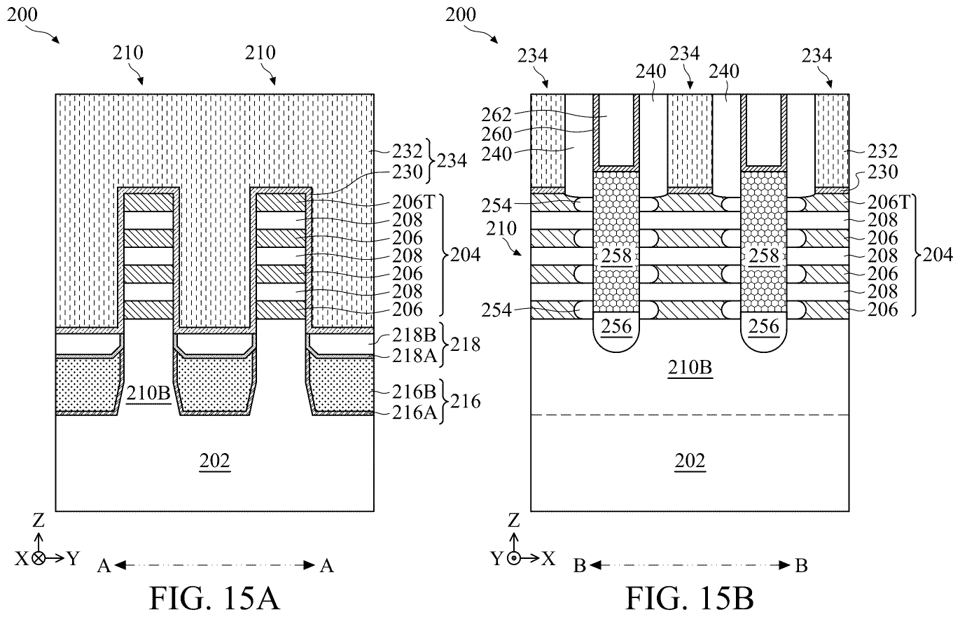

Referring to FIGS. 1, 14A-14B, and 15A-15B, the method 100 at operation 124 forms a contact etch stop layer (CESL) 260 over the epitaxial features 258 and an interlayer dielectric (ILD) layer 262 over the CESL 260. The CESL 260 may include silicon nitride, silicon oxynitride, silicon nitride with oxygen (O) or carbon (C) elements, and/or other materials; and may be formed by CVD, PVD (physical vapor deposition), ALD, or other suitable methods. The ILD layer 262 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 262 may be formed by PECVD or FCVD (flowable CVD), or other suitable methods. In some embodiments, forming the ILD layer 262 further includes performing a CMP process to planarize a top surface of the device 200, such that the mask layer 236 over top portions of the sacrificial gate structures 234 are removed, as shown in FIGS. 15A-15B.

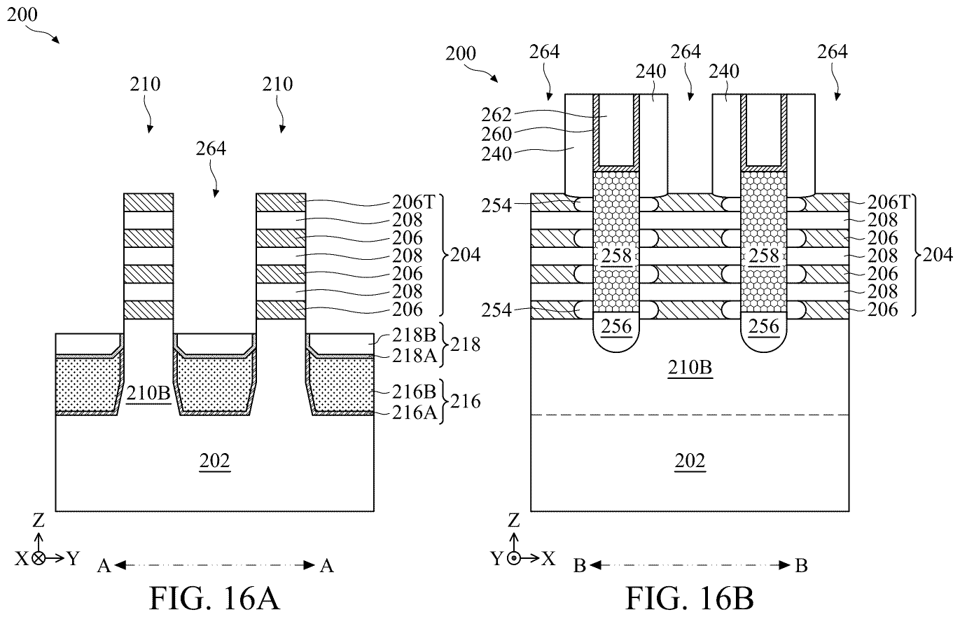

Referring to FIGS. 1 and 16A-16B, the method 100 at operation 126 removes the sacrificial gate structure 234 to form a gate trench 264. The removal of the sacrificial gate structure 234 may include one or more etching processes that are selective to the material of the sacrificial gate structure 234. For example, the removal of the sacrificial gate structure 234 may be performed using as a selective wet etch, a selective dry etch, or a combination thereof that is selective to the sacrificial gate structure 234. In one embodiment, the etching process is a reactive-ion etching (RIE). After the removal of the sacrificial gate structure 234, the top surface and sidewalls of the epitaxial stack 204 in the channel region, as well as the STI protecting layer 218, are exposed in the gate trench 264. The STI protecting layer 218 protects the underneath STI feature 216 from etching loss.

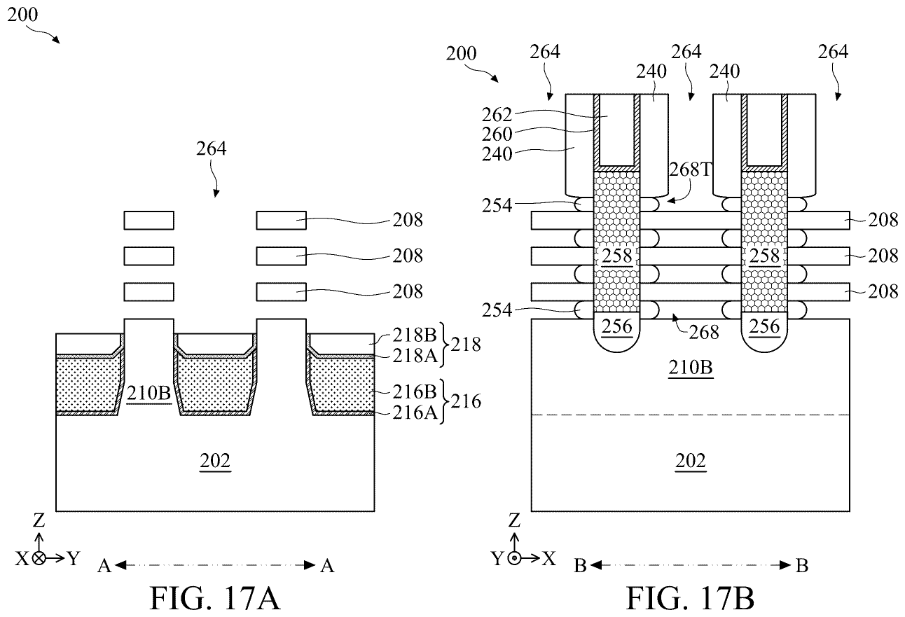

Referring to FIGS. 1 and 17A-17B, the method 100 at operation 128 selectively removes the top sacrificial layer 206T and the underneath sacrificial layers 206 from the gate trench 264 in an etch process. The selective removal of the top sacrificial layer 206T and the underneath sacrificial layers 206 releases the channel layers 208 to form channel members (also numbered as 208). The channel members 208 may also be referred to as nanostructures 208 or semiconductor nanostructures 208. The selective removal of the top sacrificial layer 206T and the underneath sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Since the topmost inner spacer 254 may be thinner than the underlying inner spacers 254, the corner region confined between the topmost inner spacer 254 and the bottom surface of the gate sidewall spacers 240 may be narrower, thereby limiting the accessibility of etchants to the top sacrificial layer 206T in this region. As previously described, the top sacrificial layer 206T may have a higher molar concentration of germanium compared to the underlying sacrificial layers 206. This increased germanium content facilitates the selective removal of the top sacrificial layer 206T, particularly in the corner regions.

Due to the etch protection provided by the top sacrificial layer 206T, the topmost channel member 208 and the underlying channel members 208 maintain substantially uniform thickness. The selective removal of the top sacrificial layer 206T results in the formation of a gap 268T between the bottom surface of the gate sidewall spacer 240 and the top surface of the topmost channel member 208. Similarly, the selective removal of the underlying sacrificial layers 206 forms gaps 268 between adjacent channel members 208. Similar to the gaps 268, the gap 268T is also confined between opposing inner spacers 254. Accordingly, the lengths of the gap 268T and the gaps 268, measured along the X direction, are substantially the same. As a result, when a metal gate is subsequently formed within the gap 268T and the gaps 268, the critical dimensions (CDs) of the metal gate above the topmost channel member 208 and between the channel members 208 are also substantially uniform.

In the depicted embodiment as shown in FIG. 17B, the height of the gap 268T, measured from the top surface of the topmost channel member 208 to the bottom surface of the gate sidewall spacers 240 along the Z direction, gradually increases from the sidewall of the topmost inner spacer 254 toward the edge of the gate sidewall spacer 240, following the curved profile of the bottom surface of the gate sidewall spacer 240. As previously discussed, the top sacrificial layer 206T may be intentionally formed with a greater thickness than the underlying sacrificial layers 206 to compensate for this tapering profile, thereby ensuring that the gap 268T maintains a sufficient height to facilitate deposition of the metal gate material.

In some alternative embodiments, the top sacrificial layer 206T together with the underlying sacrificial layers 206 may be removed after the S/D trenches 250 are formed. Thus, the channel layers 208 are released as channel members prior to the formation of the inner spacers 254. Subsequently, a sacrificial dielectric layer is deposited in space between the channel members 208 and laterally recessed to form the cavities 252. The sacrificial dielectric layer may include an oxide-based material, such as silicon oxide. The inner spacers 254 are then formed in the cavities 252. After the sacrificial gate structure 234 is removed and the gate trench 264 is formed, the sacrificial dielectric layer is removed to release the channel member again. By replacing the sacrificial layers 206 and 206T with a sacrificial dielectric layer first and later removing the sacrificial dielectric layer during the replacement gate process, an etching contrast is enhanced when the channel members are released in the gate trench, and the geometry (e.g., surface flatness) of the channel members can be better preserved.

Referring to FIGS. 1, 18A-18B, and 19A-19B, the method 100 at operation 130 forms a metal gate structure 270 in the gate trench 264. The metal gate structure 270 wrap around each of the channel members 208 in the channel region. The inner spacers 254 separate the metal gate structure 270 from contacting the epitaxial features 258.

The metal gate structure 270 includes a gate dielectric layer 272 wrapping each of the channel members 208 in the channel region and a gate electrode layer 274 formed on the gate dielectric layer 272. A dielectric constant of the gate dielectric layer 272 is greater than that of the gate sidewall spacers 240. A thickness of the gate sidewall spacers 240 is greater than that of the gate dielectric layer 272. In some embodiments, the gate dielectric layer 272 includes one or more layers of dielectric material(s). In furtherance of some embodiments, the gate dielectric layer 272 includes an interfacial layer and a high-k dielectric layer formed on the interfacial layer. The interfacial layer may be formed by an oxidization process that oxidizes exposed semiconductive surfaces of the channel members 208 and exposed semiconductive surfaces of the fin-shaped base 210B. That is, the exposed dielectric surfaces of the STI protecting layer 218 may not be directly covered by the interfacial layer. The high-k dielectric layer is then deposited over the interfacial layer using ALD, CVD, and/or other suitable methods. The exposed dielectric surfaces of the STI protecting layer 218, the inner spacers 254, and the gate sidewall spacers 240 are in contact with the high-k dielectric layer instead. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In one embodiment, the high-k dielectric layer is formed using a highly conformal deposition process such as ALD in order to ensure the formation of a gate dielectric layer having a uniform thickness around each channel members.

The gate electrode layer 274 is formed on the gate dielectric layer 272 to wrap around each of the channel members 208. The gate electrode layer 274 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 274 may be formed by CVD, ALD, electro-plating, or other suitable method. In certain embodiments of the present disclosure, one or more work function adjustment layers are interposed between the gate dielectric layer and the gate electrode layer. The work function adjustment layers are made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TiN, TiC, Co, TiAl, HfTi, TiSi and TaSi is used as the work function adjustment layer, and for the p-channel FET, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-type transistors and the p-type transistors which may use different metal layers.

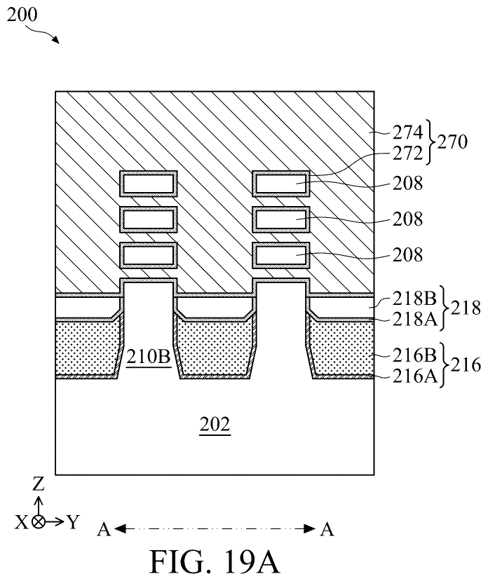

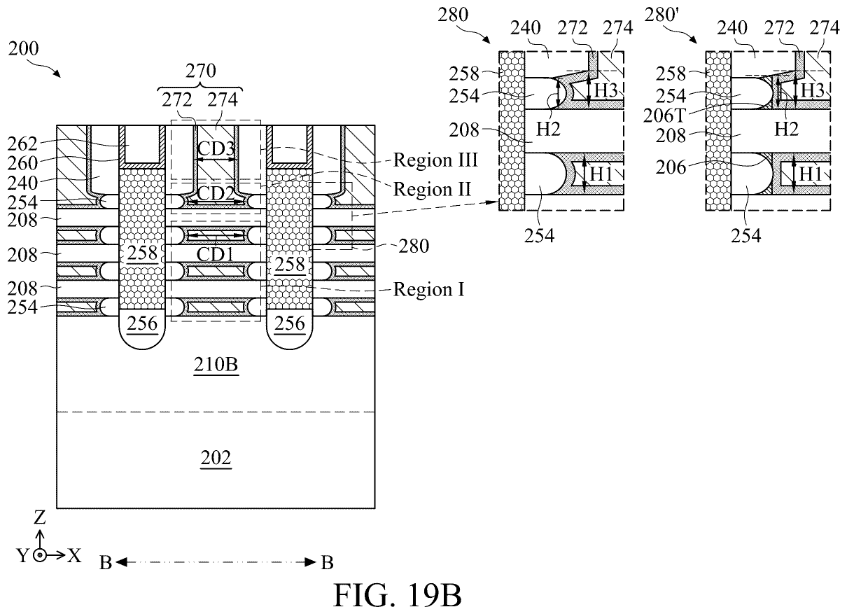

Referring to FIGS. 19A-19B, the method 100 at operation 130 may optionally include a planarization process, such as a CMP process, to remove excessive dielectric material and conductive material after the deposition of the gate dielectric layer 272 and the gate electrode layer 274. The planarization process reduces a height of the metal gate structure 270.

The metal gate structure 270 can be considered as having three portions based on its spatial relationship with the channel members 208 and the gate sidewall spacers 240. These portions are located in Region I, Region II, and Region III, as delineated by the dashed rectangular boxes in FIG. 19B. Region I is located below the topmost channel member 208. The corresponding portion of the metal gate structure 270 is positioned in the spaces between adjacent channel members 208, and is referred to as the inner metal gate. Region II is located above the topmost channel member 208 and below the bottom edge point of the inner sidewall (facing the metal gate structure 270) of the gate sidewall spacer 240. The corresponding portion of the metal gate structure 270 in Region II resides between the top surface of the topmost channel member 208 and the bottom surface of the gate sidewall spacer 240, and is referred to as the top metal gate. Region III is located between the opposing inner sidewalls of two adjacent gate sidewall spacers 240. The portion of the metal gate structure 270 that occupies this region is referred to as the outer metal gate. The top metal gate may also be considered as a bottom portion of the outer metal gate expanding under the gate sidewall spacers 240.

The inner metal gate in Region I has a first gate length (denoted as CD1), defined between opposing inner spacers 254 located beneath the topmost channel member 208. The top metal gate in Region II has a second gate length (denoted as CD2), defined between opposing topmost inner spacers 254 located above the topmost channel member 208. Since the topmost inner spacers 254 and the underlying inner spacers 254 are formed using the same process, their respective edges are substantially aligned. Accordingly, the first and second gate lengths are substantially equal (CD1=CD2). In contrast, the outer metal gate in Region III has a third gate length (denoted as CD3), defined between opposing gate sidewall spacers 240. This third gate length is determined by the formation and dimensions of the gate sidewall spacers 240, rather than the inner spacers 254, and is therefore different from the first and second gate lengths (CD3≠CD1 or CD2). By incorporating a top sacrificial layer 206T and forming additional topmost inner spacers 254 above the topmost channel member 208, the portion of the metal gate that directly contacts the top surface of the topmost channel member 208 (i.e., the top metal gate) is configured to have the same gate length as the portion that directly contacts the bottom surface of the same channel member (i.e., the inner metal gate). This symmetry improves gate length uniformity within the metal gate structure 270. In the absence of the top sacrificial layer and the topmost inner spacers 254, the metal gate structure 270 would include only the inner metal gate and the outer metal gate, resulting in different gate lengths engaging the top and bottom surfaces of the topmost channel member 208, which could lead to device performance non-uniformity.

An enlarged view of a region 280, which includes a portion of the top metal gate extending beneath the gate sidewall spacer 240 and a portion of the inner metal gate located below the topmost channel member 208, is provided to illustrate further structural details. In the illustrated embodiment, the thickness of the inner metal gate between adjacent channel members 208 (denoted as H1) is substantially uniform. By contrast, the thickness of the top metal gate, which is measured from the top surface of the topmost channel member 208 to the bottom surface of the gate sidewall spacer 240 along the Z direction, gradually increases from the topmost inner spacer 254 toward the bottom edge point of the inner sidewall of the gate sidewall spacer 240. This variation in thickness results from the curved profile of the bottom surface of the gate sidewall spacer 240. The minimum thickness (denoted as H2) of the top metal gate occurs at the corner region where the bottom surface of the gate sidewall spacer 240 meets the inner spacer 254. The maximum thickness (denoted as H3) occurs at the bottom edge point of the inner sidewall of the gate sidewall spacer 240. As previously described, the top sacrificial layer 206T may be intentionally formed with a greater thickness than the underlying sacrificial layers 206 to compensate for this tapered profile. This design choice helps ensure that the corner region maintains sufficient height to facilitate conformal deposition of the metal gate material. In some embodiments, H2 is less than H1 and H3 is greater than H1 (H2<H1<H3). In alternative embodiments, both H2 and H3 are greater than H1 (H1<H2<H3). In some embodiments, the ratio of H3 to H1 ranges from about 1.2:1 to about 2:1.

An alternative embodiment of the enlarged region, designated as 280′, is also illustrated in FIG. 19B. In this alternative embodiment, due to the limited accessibility of etchants to the narrow corner regions, residual tip portions of the top sacrificial layer 206T and the underlying sacrificial layers 206 may remain between the inner spacers 254 and the gate sidewall spacer 240, as well as between the inner spacers 254 and the channel members 208. Consequently, the sidewall of the top metal gate may interface with both the topmost inner spacer 254 and the remaining tip portions of the top sacrificial layer 206T. Similarly, the sidewall of the inner metal gate may interface with both the inner spacers 254 and the residual tip portions of the sacrificial layers 206. In some implementations, the residual tip portions may be composed of silicon germanium, but with varying germanium concentrations, which reflects in some embodiments a higher germanium content in the top sacrificial layer 206T relative to the underlying sacrificial layers 206. Other than the curved sidewall profiles bending inward toward the channel region, the sidewalls of the inner and top metal gates in this alternative embodiment may be substantially straight. In some alternative manufacturing flows, the sacrificial layers 206 and top sacrificial layer 206T may be replaced with a dielectric interposer prior to the release of the channel layers to form the channel members. In such implementations, the remaining tip portions may be composed of a dielectric material (e.g., silicon oxide) rather than a semiconductor material (e.g., silicon germanium).

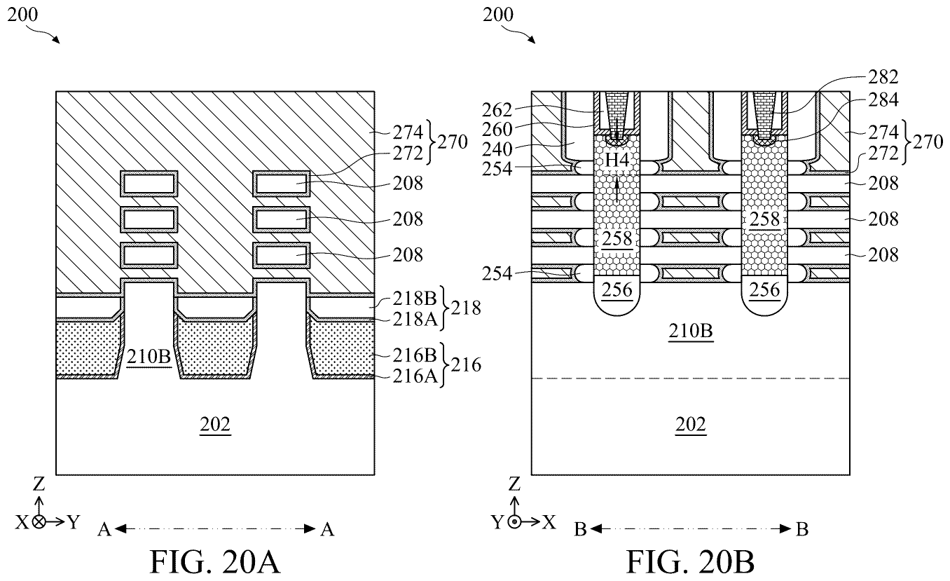

Referring to FIGS. 1 and 20A-20B, the method 100 at operation 132 forms one or more S/D contacts 282 and optional silicide features 284 between the S/D contacts 282 and the epitaxial features 258. An electrical conductivity of the S/D contacts 282 is greater than that of the epitaxial features 258. In an exemplary process, contact holes are first formed by etching through the ILD layer 262 and the CESL 260. An upper portion of the epitaxial feature 258 may optionally be etched to have a concave shape as a bottom of the contact hole. The silicide features 284 are formed at the bottom of the contact holes. The silicide features 284 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. Subsequently, S/D contacts 282 are formed on the silicide features 284. Each S/D contacts 282 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes. The silicide feature 284 and the S/D contact 282 may be collectively referred to as a S/D contact. In the depicted embodiment, due to the deposition of the top sacrificial layer 206T and the formation of extra topmost inner spacers 254, the bottom surface of the S/D contact is above the top surface of the topmost channel member 208 with a vertical distance (denoted as H4) sufficiently large for the current traveling between the S/D contact and the channel region to be more evenly distributed to other underneath channel members 208, which mitigates current crowding in the source/drain regions. In furtherance of some embodiments, the bottom surface of the S/D contact is above the top surface of the topmost inner spacers 254. In some embodiments, H4 is larger than both H2 and H3 (FIG. 19B). In some alternative embodiments, H4 is larger than H2 but smaller than H3 (i.e., H2<H4<H3).

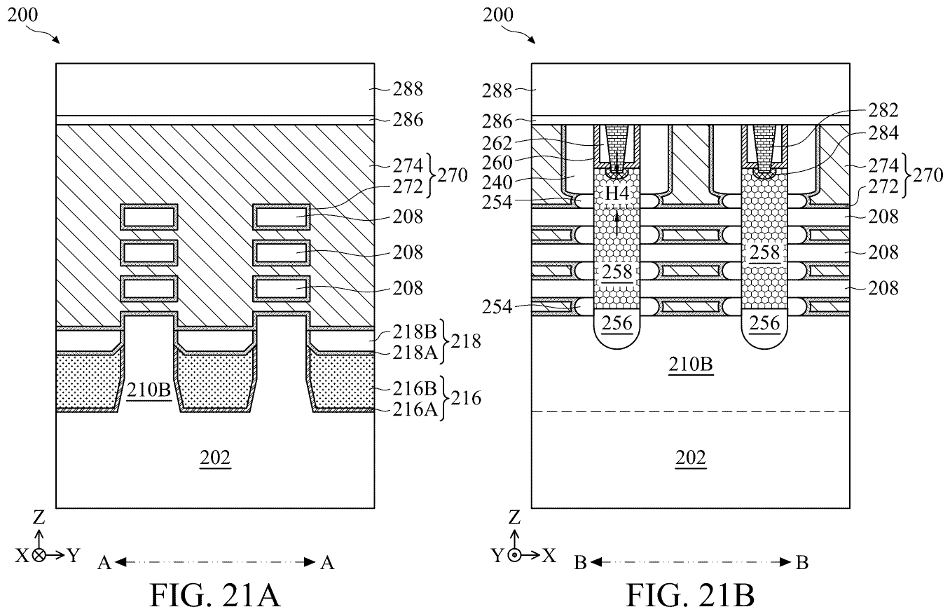

Referring to FIGS. 1 and 21A-21B, the method 100 at operation 134 deposits an etch stop layer (ESL) 286 and a dielectric layer 288 over the ESL 286. In some embodiments, the ESL 286 may comprise silicon nitride, silicon oxynitride, silicon nitride with oxygen (O) or carbon (C) elements, and/or other materials; and may be formed by CVD, PVD, ALD, or other suitable methods. The ESL 286 covers the exposed top surfaces of the metal gate structure 270, the gate sidewall spacers 240, the CESL 260, and the ILD 262. In some embodiments, the dielectric layer 288 is a second ILD layer and may comprise TEOS oxide, un-doped silicate glass, or doped silicon oxide such as BPSG, FSG, PSG, BSG, and/or other suitable dielectric materials. The dielectric layer 288 may be formed by PECVD, FCVD, or other suitable methods.

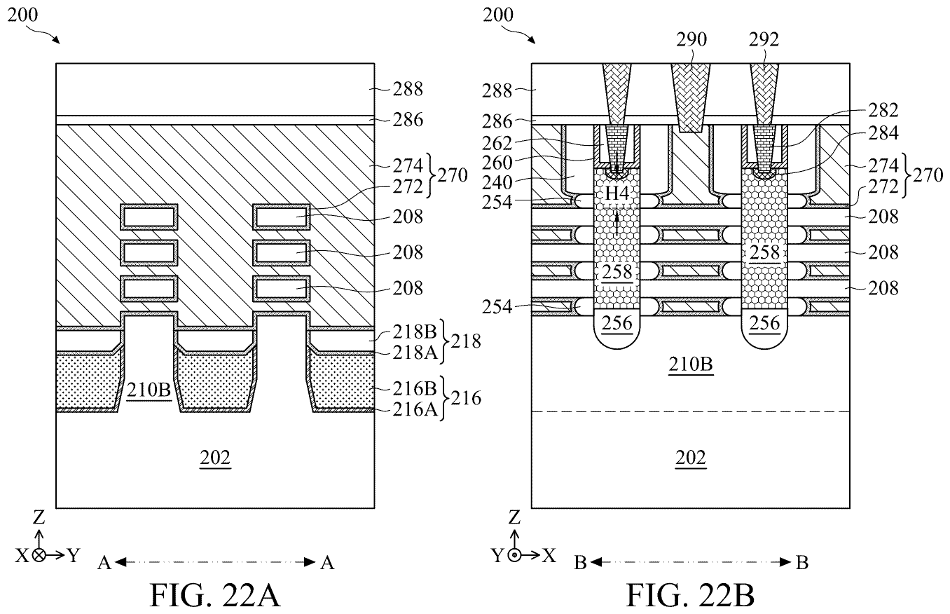

Referring to FIGS. 1 and 22A-22B, the method 100 at operation 136 forms a gate via 290 over and in electrical coupling with the metal gate structure 270 and S/D contact vias 292 over and in electrical coupling with the S/D contacts 282. Each of the gate via 290 and the S/D contact vias 292 extends through the dielectric layer 288 and the ESL 286. The forming of the gate via 290 and the S/D contact vias 292 includes forming plug holes through respective dielectric layers by an etching process and depositing conductive materials in the plug holes as the gate via 290 and the S/D contact vias 292, respectively. In an embodiment, the conductive materials include a barrier layer (such as TaN or TiN) and a metal fill layer (such as Al, Cu, or W). The layers in the conductive materials may be deposited using CVD, PVD, PECVD, ALD, plating, or other suitable methods. Further, the etching process may over etch to improve contact surface areas and reduce contact resistance, such that the gate via 290 and/or the S/D contact vias 292 may extend beneath the plane in which the top surface of the metal gate structure 270 resides.

FIG. 23 illustrates an alternative embodiment of device 200 at the conclusion of operation 136. Many features of device 200 as shown in FIG. 23 are the same as, or similar to, those depicted in FIG. 22B. One notable difference is that the outer metal gate in FIG. 23 exhibits slanted sidewalls rather than vertical sidewalls. This variation arises because the formation of the gate trench 264 may also result in partial etching of the gate sidewall spacers 240, due to limited etching selectivity. As a result, some material loss occurs along the sidewalls of the gate sidewall spacers 240, thereby contributing to the slanted profile of the outer metal gate.

FIG. 24 illustrates another alternative embodiment of device 200 at the conclusion of operation 136. Many features of device 200 as shown in FIG. 24 are the same as, or similar to, those depicted in FIG. 22B. One notable difference is that the top and bottom surfaces of the channel members 208 may exhibit a curved profile. This variation arises because the etching process used to release the channel layers may also cause the channel layers to experience some etching loss, due to limited etching selectivity. As a result, the originally flat surfaces of the channel members 208 may become curved.

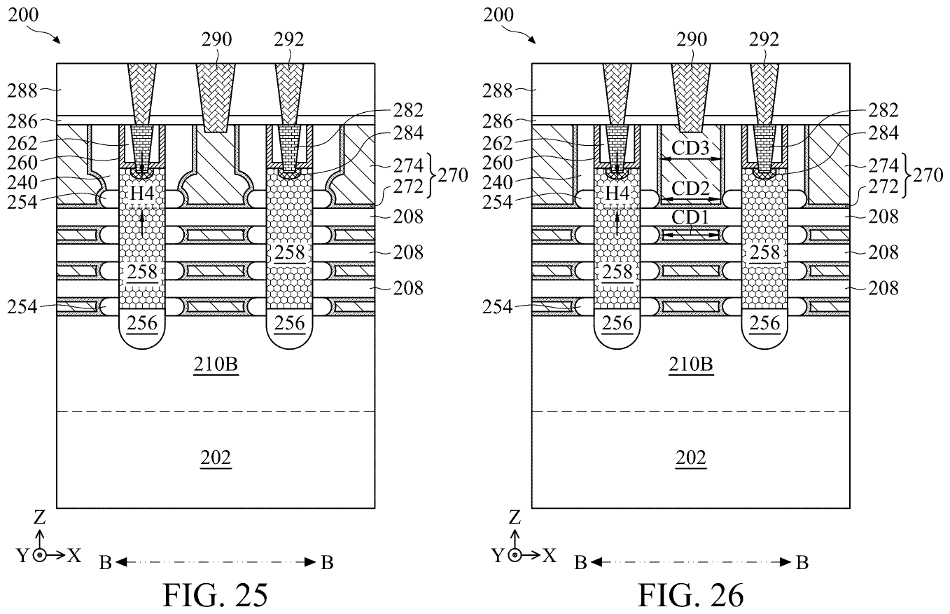

FIG. 25 illustrates another alternative embodiment of device 200 at the conclusion of operation 136. Many features of device 200 as shown in FIG. 25 are the same as, or similar to, those depicted in FIG. 22B. One notable difference is that the bottom portion of the inner sidewalls of the gate sidewall spacers 240 may bend outward away from the metal gate structure 270, such that the inner sidewalls of the gate sidewall spacers 240 exhibit a top straight profile and a bottom curved profile. This variation arises because the etching process used to remove the top sacrificial layer 206T may also cause the bottom portion of the gate sidewall spacers 240 to experience some etching loss, due to limited etching selectivity. As a result, the originally vertical inner sidewalls of the gate sidewall spacers 240 may further include a bottom curved portion.

FIG. 26 illustrates another alternative embodiment of device 200 at the conclusion of operation 136. Many features of device 200 as shown in FIG. 26 are the same as, or similar to, those depicted in FIG. 22B. One notable difference is that the outer metal gate and the top metal gate, as well as the inner metal gate, may have the same gate length (i.e., CD1=CD2=CD3). This variation arises when the gate trench 264 is formed in a way that it has the same gate trench width from top to bottom. As a result, the metal gate structure 270 has the same CD from top to bottom.

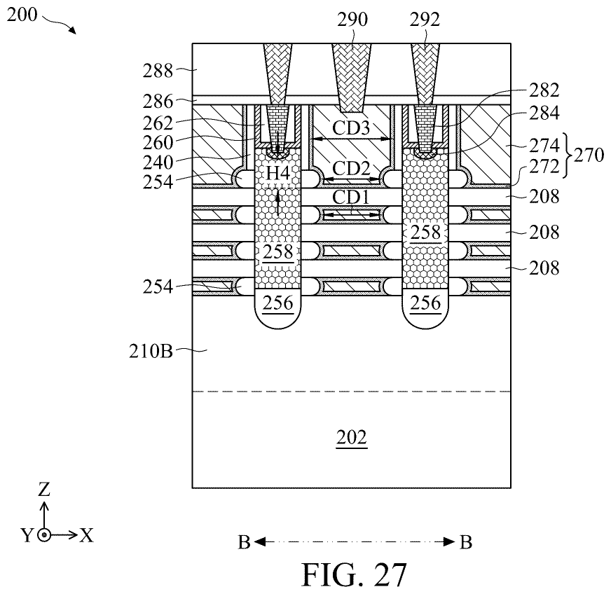

FIG. 27 illustrates another alternative embodiment of device 200 at the conclusion of operation 136. Many features of device 200 as shown in FIG. 27 are the same as, or similar to, those depicted in FIG. 22B. One notable difference is that the outer metal gate has a gate length larger than that of the top metal gate and the inner metal gate (i.e., CD3>CD2=CD1). This variation arises when during the formation of the inner spacers 254, the cavities 252 extend beyond the plane of the inner sidewalls of the gate sidewall spacers 240, such that the inner spacers 254 extend to a position directly under the metal gate structure 270. As a result, the outer metal gate has a larger gate length than that of the top metal gate and the inner metal gate.

Notably, the various embodiments illustrated in FIGS. 22B-27 may also incorporate the alternative configuration of region 280 (FIG. 19B), in which residual tip portions of the top sacrificial layer 206T and the sacrificial layers 206 (or, in some implementations, the dielectric interposer that replaces the top sacrificial layer 206T and the sacrificial layers 206) remain in the final device structure.

At operation 138, the method 100 (FIG. 1) performs further steps to complete the fabrication of the device 200. For example, the method 100 may form metal interconnects electrically connecting the source/drain contact vias and gate vias of various transistors to form a complete IC.

Although not intended to be limiting, embodiments of the present disclosure provide one or more of the following advantages. For example, embodiments of the present disclosure form a top sacrificial layer above the topmost channel layer. This advantageously improves the uniformity of the channel member thickness and the metal gate CD in the channel region, as well as reducing current crowding in the source/drain regions. Further, embodiments of the present disclosure can be readily integrated into existing semiconductor manufacturing processes.

In one exemplary aspect, the present disclosure is directed to a method. The method includes forming a stack over a substrate, the stack comprising a plurality of channel layers interleaved by a plurality of sacrificial layers, a topmost one of the sacrificial layers above a topmost one of the channel layers, patterning the stack to form a fin-shaped structure, the fin-shaped structure comprising a channel region and a source/drain region, forming a dummy gate stack over the channel region of the fin-shaped structure, depositing a gate sidewall spacer extending along a sidewall of the dummy gate stack, recessing the fin-shaped structure in the source/drain region to form a source/drain trench that exposes sidewalls of the channel layers and the sacrificial layers, forming an epitaxial feature in the source/drain trench, the epitaxial feature interfacing the channel layers, removing the dummy gate stack to form a gate trench, releasing the channel layers in the channel region as a plurality of channel members by removing the sacrificial layers, forming a metal gate structure in the gate trench, the metal gate structure wrapping around at least one of the channel members, the metal gate structure including a first portion above a topmost one of the channel members and interfacing with a bottom surface of the gate sidewall spacer, forming an interlayer dielectric layer over the epitaxial feature, and forming a contact extending through the interlayer dielectric layer to electrically couple to the epitaxial feature. An electrical conductivity of the contact is greater than an electrical conductivity of the epitaxial feature. In some embodiments, the metal gate structure includes a second portion disposed in gaps between adjacent ones of the channel members, and a gate length of the first portion equals a gate length of the second portion measured along a longitudinal direction of the channel members. In some embodiments, the metal gate structure includes a third portion above the first portion and interfacing a sidewall of the gate sidewall spacer, and a gate length of the third portion is smaller than the gate length of the first portion measured along the longitudinal direction of the channel members. In some embodiments, the method further includes partially recessing the sacrificial layers to form a plurality of inner spacer cavities, and forming a plurality of inner spacers in the inner spacer cavities. A topmost one of the inner spacers is above the topmost one of the channel members. In some embodiments, the topmost one of the inner spacers interfaces the first portion of the metal gate structure. In some embodiments, the topmost one of the inner spacers is thinner than underneath ones of the inner spacers. In some embodiments, after the forming of the dummy gate stack and prior to the depositing of the gate sidewall spacer, a top surface of the topmost one of the sacrificial layers has a dishing profile. In some embodiments, the bottom surface of the gate sidewall spacer has a curvature profile. In some embodiments, a thickness of the topmost one of the sacrificial layers is greater than a thickness of underneath ones of the sacrificial layers. In some embodiments, the sacrificial layers include germanium, and the topmost one of the sacrificial layers and underneath ones of the sacrificial layers differ at least in germanium concentration in molar ratio.

In another exemplary aspect, the present disclosure is directed to a method. The method includes forming an isolation feature over a substrate, forming a fin-shaped structure protruding from the substrate and through the isolation feature, the fin-shaped structure comprising a plurality of channel layers interleaved by a plurality of sacrificial layers, a topmost one of the channel layers positioned under a topmost one of the sacrificial layers, forming a sacrificial gate structure across the fin-shaped structure, depositing a gate sidewall spacer extending along a sidewall of the sacrificial gate structure, removing the sacrificial gate structure to form a gate trench, removing the sacrificial layers form the gate trench, the removing of the sacrificial layers exposing a bottom surface of the gate sidewall spacer, and depositing a metal gate structure in the gate trench, the metal gate structure including a first portion above the topmost one of the channel layers and a second portion in gaps between adjacent ones of the channel layers, an interface between the first portion of the metal gate structure and the bottom surface of the gate sidewall spacer having a slope profile. In some embodiments, the first and second portions of the metal gate structure include a same gate length. In some embodiments, the metal gate structure includes a third portion above the first portion and interfacing a sidewall of the gate sidewall spacer, the third portion is narrower than the first portion. In some embodiments, after the removing of the sacrificial layers, each of the channel layers has a uniform thickness. In some embodiments, the method further includes recessing the fin-shaped structure in a region adjacent to the gate sidewall spacer to form a trench that exposes the channel layers and the sacrificial layers, partially recessing the sacrificial layers to form a plurality of cavities, and forming a plurality of inner spacers in the cavities. A topmost one of the inner spacers is positioned above a top surface of the topmost one of the channel layers. In some embodiments, the first portion of the metal gate structure has a thickness increasing towards a center of the metal gate structure.

In another exemplary aspect, the present disclosure is directed to a semiconductor device. The semiconductor device includes semiconductor nanostructures disposed over a substrate, an epitaxial feature abutting the semiconductor nanostructures, a metal gate structure wrapping around at least one of the semiconductor nanostructures, the metal gate structure including a gate dielectric layer and a gate electrode over the gate dielectric layer, and a gate spacer extending along a sidewall of the metal gate structure. A dielectric constant of the gate dielectric layer is greater than a dielectric constant of the gate spacer, and a first portion of the metal gate structure has a bottom surface between a top surface of a topmost semiconductor nanostructure and a bottom surface of the gate spacer. In some embodiments, a second portion of the metal gate structure is vertically stacked between adjacent ones of the semiconductor nanostructures, and a gate length of the first portion of the metal gate structure equals a gate length of the second portion of the metal gate structure measured along a longitudinal direction of the semiconductor nanostructures. In some embodiments, the semiconductor device further includes inner spacers interleaving the semiconductor nanostructures, and a topmost inner spacer is above and interfacing the top surface of the topmost semiconductor nanostructure. In some embodiments, the bottom surface of the gate spacer has a curvature shape.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
forming a stack over a substrate, the stack comprising a plurality of channel layers interleaved by a plurality of sacrificial layers, a topmost one of the sacrificial layers above a topmost one of the channel layers;
patterning the stack to form a fin-shaped structure, the fin-shaped structure comprising a channel region and a source/drain region;
forming a dummy gate stack over the channel region of the fin-shaped structure;
depositing a gate sidewall spacer extending along a sidewall of the dummy gate stack;
recessing the fin-shaped structure in the source/drain region to form a source/drain trench that exposes sidewalls of the channel layers and the sacrificial layers;
forming an epitaxial feature in the source/drain trench, the epitaxial feature interfacing the channel layers;
removing the dummy gate stack to form a gate trench;
releasing the channel layers in the channel region as a plurality of channel members by removing the sacrificial layers;
forming a metal gate structure in the gate trench, the metal gate structure wrapping around at least one of the channel members, the metal gate structure including a first portion above a topmost one of the channel members and interfacing with a bottom surface of the gate sidewall spacer;
forming an interlayer dielectric layer over the epitaxial feature; and
forming a contact extending through the interlayer dielectric layer to electrically couple to the epitaxial feature, wherein an electrical conductivity of the contact is greater than an electrical conductivity of the epitaxial feature.

2. The method of claim 1, wherein the metal gate structure includes a second portion disposed in gaps between adjacent ones of the channel members, wherein a gate length of the first portion equals a gate length of the second portion measured along a longitudinal direction of the channel members.

3. The method of claim 2, wherein the metal gate structure includes a third portion above the first portion and interfacing a sidewall of the gate sidewall spacer, wherein a gate length of the third portion is smaller than the gate length of the first portion measured along the longitudinal direction of the channel members.

4. The method of claim 1, further comprising:
partially recessing the sacrificial layers to form a plurality of inner spacer cavities; and
forming a plurality of inner spacers in the inner spacer cavities,
wherein a topmost one of the inner spacers is above the topmost one of the channel members.

5. The method of claim 4, wherein the topmost one of the inner spacers interfaces the first portion of the metal gate structure.

6. The method of claim 4, wherein the topmost one of the inner spacers is thinner than underneath ones of the inner spacers.

7. The method of claim 1, wherein after the forming of the dummy gate stack and prior to the depositing of the gate sidewall spacer, a top surface of the topmost one of the sacrificial layers has a dishing profile.

8. The method of claim 1, wherein the bottom surface of the gate sidewall spacer has a curvature profile.

9. The method of claim 1, wherein a thickness of the topmost one of the sacrificial layers is greater than a thickness of underneath ones of the sacrificial layers.

10. The method of claim 1, wherein the sacrificial layers include germanium, wherein the topmost one of the sacrificial layers and underneath ones of the sacrificial layers differ at least in germanium concentration in molar ratio.

11. A method, comprising:
forming an isolation feature over a substrate;
forming a fin-shaped structure protruding from the substrate and through the isolation feature, the fin-shaped structure comprising a plurality of channel layers interleaved by a plurality of sacrificial layers, a topmost one of the channel layers positioned under a topmost one of the sacrificial layers;
forming a sacrificial gate structure across the fin-shaped structure;
depositing a gate sidewall spacer extending along a sidewall of the sacrificial gate structure;
removing the sacrificial gate structure to form a gate trench;
removing the sacrificial layers form the gate trench, the removing of the sacrificial layers exposing a bottom surface of the gate sidewall spacer; and
depositing a metal gate structure in the gate trench, the metal gate structure including a first portion above the topmost one of the channel layers and a second portion in gaps between adjacent ones of the channel layers, an interface between the first portion of the metal gate structure and the bottom surface of the gate sidewall spacer having a slope profile.

12. The method of claim 11, wherein the first and second portions of the metal gate structure include a same gate length.

13. The method of claim 11, wherein the metal gate structure includes a third portion above the first portion and interfacing a sidewall of the gate sidewall spacer, the third portion is narrower than the first portion.

14. The method of claim 11, wherein after the removing of the sacrificial layers, each of the channel layers has a uniform thickness.

15. The method of claim 11, further comprising:
recessing the fin-shaped structure in a region adjacent to the gate sidewall spacer to form a trench that exposes the channel layers and the sacrificial layers;
partially recessing the sacrificial layers to form a plurality of cavities; and
forming a plurality of inner spacers in the cavities, wherein a topmost one of the inner spacers is positioned above a top surface of the topmost one of the channel layers.

16. The method of claim 11, wherein the first portion of the metal gate structure has a thickness increasing towards a center of the metal gate structure.

17. A semiconductor device, comprising:
a plurality of semiconductor nanostructures disposed over a substrate;
an epitaxial feature abutting the semiconductor nanostructures;
a metal gate structure wrapping around at least one of the semiconductor nanostructures, wherein the metal gate structure includes a gate dielectric layer and a gate electrode over the gate dielectric layer; and
a gate spacer extending along a sidewall of the metal gate structure,
wherein a dielectric constant of the gate dielectric layer is greater than a dielectric constant of the gate spacer, and wherein a first portion of the metal gate structure has a bottom surface between a top surface of a topmost semiconductor nanostructure and a bottom surface of the gate spacer.

18. The semiconductor device of claim 17, wherein a second portion of the metal gate structure is vertically stacked between adjacent ones of the semiconductor nanostructures, wherein a gate length of the first portion of the metal gate structure equals a gate length of the second portion of the metal gate structure measured along a longitudinal direction of the semiconductor nanostructures.

19. The semiconductor device of claim 17, further comprising:
a plurality of inner spacers interleaving the semiconductor nanostructures,
wherein a topmost inner spacer is above and interfacing the top surface of the topmost semiconductor nanostructure.

20. The semiconductor device of claim 17, the bottom surface of the gate spacer has a curvature shape.
